(19) United States
(12) Patent Application Publication
(10) Pub. No.: US 2026/0202854 A1
(43) Pub. Date: Jul. 16, 2026

(54) SMART LOGISTICS VEHICLE CONTROL METHOD AND CONTROL SYSTEM

(71) Applicants: Hyundai Motor Company, Seoul (KR); Kia Corporation, Seoul (KR)

(72) Inventors: Kyung Dong PARK, Gyeonggi-do (KR); Man Ki LEE, Gyeonggi-do (KR); Kye Un AHN, Gyeonggi-do (KR)

(21) Appl. No.: 19/136,055

(22) PCT Filed: Apr. 6, 2023
(86) PCT No.: PCT/KR2023/004655

§ 371 Date: Jun. 5, 2025

(30) Foreign Application Priority Data
Mar. 21, 2023 (KR) 10-2023-0036677

(51) Int. Cl. G05D 1/644; B60L 58/12; G05D 1/698; G05D 107/70; G05D 109/10; G06Q 10/08

(52) U.S. Cl. CPC G05D 1/644; B60L 58/12; G05D 1/6987; G06Q 10/08; G05D 2107/70; G05D 2109/10

(57) ABSTRACT

Introduced are a smart logistics vehicle control method and a control system, the method including the steps of: controlling a smart logistics vehicle not performing an operation, among multiple smart logistics vehicles, to perform a circling operation along a preconfigured patrol route; determining whether a smart logistics vehicle is required for each of multiple process areas; when at least one of the multiple process areas requires a smart logistics vehicle, selecting at least one smart logistics vehicle from among smart logistics vehicles performing the circling operation; and controlling the at least one selected smart logistics vehicle to end the circling operation, move to the at least one process area, and perform a logistics operation.

### CROSS-REFERENCE TO RELATED APPLICATIONS

This application is the U.S. National Phase under 35 U.S.C. § 371 of International Patent Application No. PCT/KR2023/004655, filed on Apr. 6, 2023, which in turn claims the benefit of Korean Application No. 10-2023-0036677, filed on Mar. 21, 2023, the entire disclosures of which applications are incorporated by reference herein.

### TECHNICAL FIELD

The present disclosure relates to a smart logistics vehicle control method and a control system capable of efficient operation.

### BACKGROUND ART

In recent years, smart logistics vehicles have been introduced for flexible and efficient supply and transportation of parts, not only in general logistics warehouses and factories, but also in smart factories that manufacture products with different specifications using various parts.

Smart logistics vehicles are a concept that collectively refers to autonomous mobile robots (AMRs) and automated guided vehicles (AGVs), and these smart logistics vehicles can perform movements and operations under a control of a control system.

In the smart factory where the smart logistics vehicle and the control system are applied, a method of operating the smart logistics vehicle can affect each process configured in the smart factory. For example, when a mission for moving and performing an operation is not input to the smart logistics vehicle, the smart logistics vehicle may remain stationary at the location where the movement or operation is completed. In this case, when the smart logistics vehicle is required in each process, such as when it is necessary to perform logistics transfers between processes, the stationary smart logistics vehicle will be utilized. However, when the stationary smart logistics vehicle is located far away from the process that requires the smart logistics vehicle, it takes a long time to move to the corresponding process, which immediately affects the process rate or production volume of the entire process.

Therefore, it is necessary to propose a method of operating the smart logistics vehicle, which does not affect the process rate or production volume of the entire process.

The matters described as background technology above are only intended to enhance understanding of the background of the present disclosure, and should not be taken as an acknowledgment that they correspond to prior art already known to those skilled in the art.

### DISCLOSURE

### Technical Problem

The present disclosure is to provide a smart logistics vehicle control method and a control system capable of efficiently operating a plurality of smart logistics vehicles.

The technical tasks to be achieved by the present disclosure are not limited to the technical tasks mentioned above, and other technical tasks not mentioned may be clearly understood by those skilled in the art to which the present disclosure belongs from the following description.

### Technical Solution

A smart logistics vehicle control method according to the present disclosure for achieving the objectives includes controlling a smart logistics vehicle not performing an operation among a plurality of smart logistics vehicles to perform a circling operation along a preset patrol path, determining whether the smart logistics vehicle is necessary for each of a plurality of process zones, selecting at least one smart logistics vehicle among the smart logistics vehicles performing the circling operation when the smart logistics vehicle is necessary for at least one process zone among the plurality of process zones, and controlling the at least one selected smart logistics vehicle to stop performing the circling operation and to move to the at least one process zone and perform a logistics operation.

In addition, a smart logistics vehicle control system according to the present disclosure for achieving the objectives includes a plurality of smart logistics vehicles, a plurality of production devices, each provided in a plurality of process zones, for controlling each process zone and collecting and providing process information, and an operation schedule management unit for controlling the smart logistics vehicle not performing an operation among the plurality of smart logistics vehicles to perform a circling operation along a preset patrol path, selecting at least one smart logistics vehicle among the smart logistics vehicles performing the circling operation when the smart logistics vehicle is necessary for at least one process zone among the plurality of process zones by determining whether the smart logistics vehicle is required on the basis of the process information, and controlling the at least one selected smart logistics vehicle to finish performing the circling operation and to move to the at least one process zone and perform a logistics operation.

### Advantageous Effects

According to a smart logistics vehicle control method and a control system of the present disclosure, it is possible to efficiently perform process operations using smart logistics vehicles by managing a plurality of smart logistics vehicles into a plurality of groups in which each group performs a different operation, and controlling each of the plurality of smart logistics vehicles to perform operations corresponding to the plurality of groups.

The effects obtainable in the present disclosure are not limited to the effects mentioned above, and other effects not mentioned may be clearly understood by those skilled in the art to which the present disclosure belongs from the following description.

### DESCRIPTION OF DRAWINGS

FIG. 1 is a block diagram showing an example of a smart factory configuration applicable to exemplary embodiments of the present disclosure.

FIG. 2 is a block diagram showing an example of a control device configuration applicable to exemplary embodiments of the present disclosure.

FIG. 3 is a block diagram showing an example of a smart logistics vehicle configuration applicable to exemplary embodiments of the present disclosure.

FIG. 4 is a perspective view showing an example of a smart logistics vehicle exterior applicable to exemplary embodiments of the present disclosure.

FIG. 5 is a flowchart showing an example of a traveling process of a smart logistics vehicle 110 applicable to exemplary embodiments of the present disclosure.

FIG. 6 is a block diagram showing a configuration of a smart logistics vehicle control system according to an exemplary embodiment of the present disclosure.

FIG. 7 is a view illustrating a smart logistics vehicle control system according to an exemplary embodiment of the present disclosure.

FIG. 8 is a view illustrating a smart logistics vehicle control method according to an exemplary embodiment of the present disclosure.

### MODE FOR INVENTION

In describing an exemplary embodiment disclosed in the present specification, the detailed description thereof will be omitted when it is determined that a detailed description of a related known technology may obscure the gist of the exemplary embodiments disclosed in the present specification. In addition, the accompanying drawings are only intended to facilitate an easy understanding of the exemplary embodiments disclosed in the present specification, and the technical ideas disclosed in the present specification are not limited by the accompanying drawings, and should be understood to include all modifications, equivalents, or substitutes included in the ideas and technical scope of the present disclosure.

Terms including ordinal numbers, such as first and second, may be used to describe various components, but the components are not limited by the terms. The terms are used only for the purpose of distinguishing one component from another component.

When it is mentioned that a component is “connected” or “linked” to another component, it should be understood that it may be directly connected or linked to that other component, but that there may be other components in between. On the other hand, when it is mentioned that a component is “directly connected” or “directly linked” to another component, it should be understood that there are no other components in between.

Singular expressions may include plural expressions unless the context clearly indicates otherwise.

In the present specification, terms such as “include” or “have” are intended to specify the presence of features, numbers, steps, operations, components, parts, or combinations thereof described in the specification, and are not intended to preclude in advance the presence or addition of one or more other features, numbers, steps, operations, components, parts, or combinations thereof.

Hereinafter, the exemplary embodiments disclosed in the present specification will be described in detail with reference to the accompanying drawings, and identical or similar components will be assigned the same reference numbers regardless of the drawing code, and duplicate descriptions thereof will be omitted.

In addition, a unit or control unit included in the internal configuration name of a smart logistics vehicle or control device is only a term widely used to name a control device (controller) that controls a specific function, and does not mean a generic function unit. For example, each control device may include a modem/transceiver for communicating with other control devices or sensors in order to control a function in charge, a memory for storing an operating system or logic commands and input/output information, and one or more processors for performing determination, calculation, decision, etc. necessary for a control of the function in charge. Depending on an implementation, one processor may be in charge of calculations for a plurality of control devices.

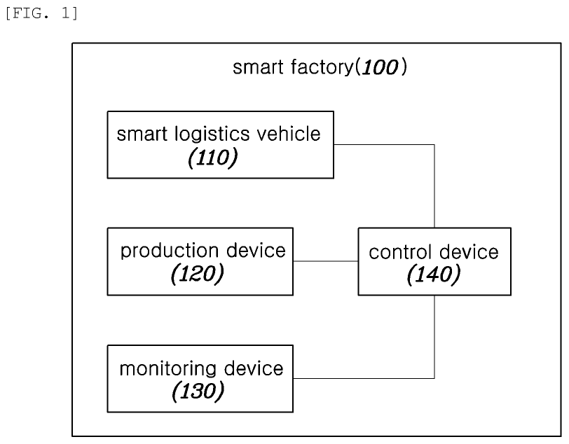

First, a configuration of a smart factory in which a smart logistics vehicle is arranged and operated according to an exemplary embodiment will be described with reference to FIG. 1.

FIG. 1 is a block diagram showing an example of a smart factory configuration applicable to exemplary embodiments of the present disclosure.

Referring to FIG. 1, the smart factory 100 may include a smart logistics vehicle 110, a production device 120, a monitoring device 130, and a control device 140.

The smart factory 100 may be provided with a plurality of smart logistics vehicles 110, a plurality of production devices 120, and a plurality of monitoring devices 130 according to a production process and a target production speed of a product. Hereinafter, each component will be described.

First, the smart logistics vehicle 110 may include an autonomous mobile robot (hereinafter, referred to as an “AMR” for convenience) and an automated guided vehicle (hereinafter, referred to as an “AGV” for convenience). Depending on an operation policy of the smart logistics vehicle 110, only one of the AGV and the AMR may be operated in the smart factory 100, or the AGV and the AMR may be operated together in a single smart factory 100.

The AGV may generally perform an operation (moving, turning, stopping, etc.) required within the smart factory 100 by recognizing and following a guidance facility placed on the floor for guiding the AGV. Herein, the guidance facility may mean an optically recognizable marker (spot, 2D code, etc.), a tag contactlessly recognizable at close range (e.g., NFC tag, RFID tag, etc.), a magnetic strip, a wire, etc., but this is merely exemplary and is not necessarily limited thereto. The guidance facility may be arranged continuously on the floor or may be arranged discontinuously spaced apart from each other. Since the AGV basically performs its operation by recognizing and following the guidance facility, it may require the guidance facility to be installed in advance before operations, so when the AGV needs to move to a new path or an existing path needs to be modified, it is necessary to physically install or modify the guidance facility. In addition, since the AGV does not deviate from the path set through the guidance facility, when an obstacle is detected on or around the path, it is common for the AGV to stop until the detected obstacle disappears or until receiving a separate control. In operating the AGV, the control device 140 may need to control the AGV on the basis of the guidance facility, so may transmit commands such as “driving from the current location until a third marker is recognized”, “switching the heading direction by 90 degrees when the third marker is recognized”, and the like to the AGV in a unit of individual commands or in a unit of missions including a plurality of commands (e.g., collect, supply, charging, patrol, etc.).

What is the most distinguished from the AGV may be that the AMR can determine the current location by sensing the surroundings (i.e., positioning) and is capable of its own path planning by using a positioning and a map. Therefore, when the AMR and the control device 140 share a coordinate-compatible map, the control device 140 may control the AMR in a way of instructing the AMR on a path based on coordinates. In addition, when an obstacle is detected while traveling, the AMR may set an avoidance path on its own to avoid the obstacle and then return to the original path. A function of the control device 140 setting the AMR path by using one or more waypoint coordinates may be referred to as global path planning, and a function of the AMR setting a movement path or setting an avoidance path between the waypoint coordinates based on the global path planning may be referred to as local path planning.

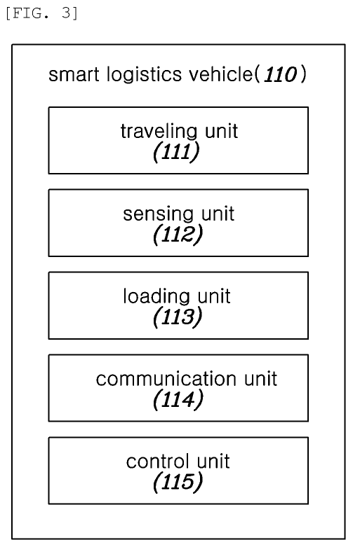

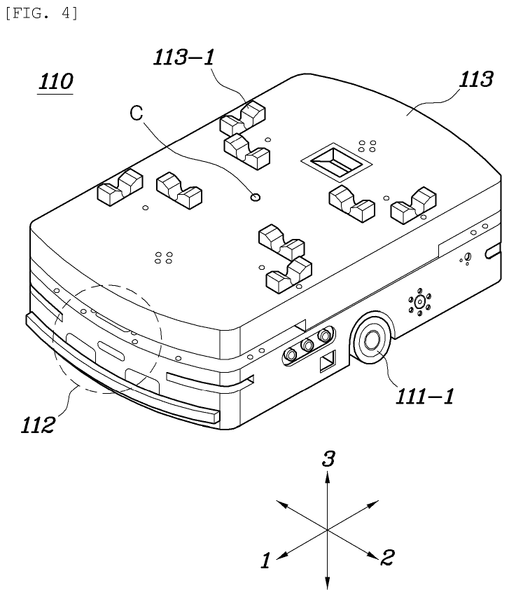

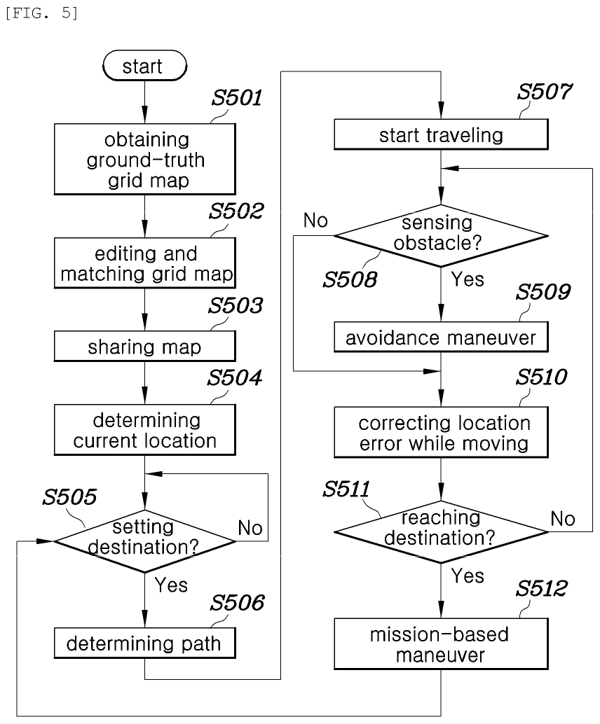

A more detailed configuration of the smart logistics vehicle 110 will be described later with reference to FIGS. 3 and 4, and a traveling control process of the AMR will be described later with reference to FIG. 5, respectively.

Next, the production device 120 may refer to a device (e.g., robot arm, conveyor belt, etc.) for performing the production process of the product in the smart factory 100, and in a broader sense, may refer to a device placed to assist in performing missions such as an entry and exit of the smart logistics vehicle 110 when the production process is performed by a person. Devices placed to assist in performing a mission may be a device for detecting the status of a designated location where a pallet carried by the smart logistics vehicle 110 can be dropped off or collected within an area where a specific production process is performed, a device for determining the extent of the process progress, and a means for blocking an entry into the area, but are not limited thereto.

For example, the production device 120 may be controlled through a programmable logic controller (PLC) and can communicate with the control device 140 in relation to the process progress.

The monitoring device 130 may perform a function of obtaining information for determining a situation in the smart factory 100 and transmitting the information to the control device 140. For example, the monitoring device 130 may include a camera, a proximity sensor, and the like, but is not limited thereto.

The control device 140 may obtain information necessary to operate the smart factory 100 or may control each component, by communicating with the aforementioned components (110, 120, and 130). For example, the control device 140 may perform dispatching of smart logistics vehicles 110, path setting, mission assignment, process management per product, material management, and the like.

In an implementation, the control device 140 may include a local control device (ACS: AMR/AGV Control System) for controlling surrounding process facilities on the basis of the location of the AGV/AMR and performing a mission-based control of the AGV/AMR, and an integrated control device (MoRIMS: Mobile Robot Integrated Monitoring System) for integrating and controlling two or more local control devices. The integrated control device may perform setting and controlling the status and path of all smart logistics robots 110 in the smart factory 100, logistics flow, and traffic from each of the plurality of local control devices. For example, when the local control device (ACS) is provided in a unit of smart logistics robots of the same manufacturer or the same model, the integrated control device may perform an integrated control for collision prevention, such as a bottleneck level analysis of intersection/overlap areas, a driving acceleration/deceleration control, and an avoidance path regeneration, through a heterogeneous traffic distribution control based on the information obtained through the plurality of local control devices (ACS).

Moreover, the integrated control device can also have a manufacturing execution system (MES) as its higher control entity, and the manufacturing execution system (MES) can be linked again to an automated scheduler (APS: Advanced Planning & Scheduling).

In addition to the configurations 110, 120, 130, 140 of the smart factory 100 described above, a device for mutual communication between each component, such as beacons, repeaters, and APs (Access Points), a chargers for charging the smart logistics vehicles 110, a loading space for storing or loading parts, a space for storing a finished product or an intermediate product, a traffic light, a barrier, a waiting space for idle smart logistics vehicles 110, and the like may be appropriately arranged within the smart factory 100.

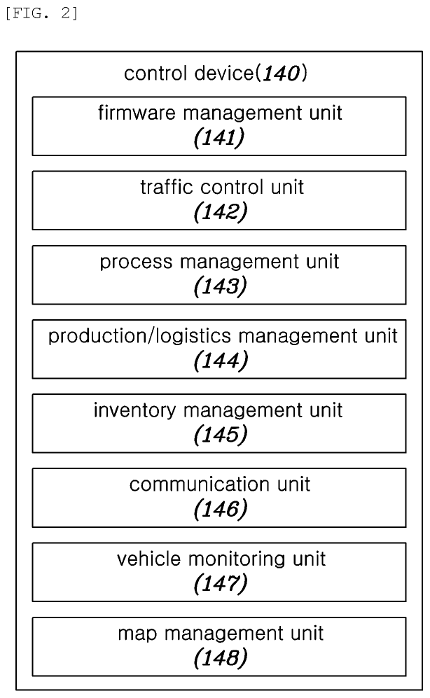

Hereinafter, a configuration of the control device 140 applicable to exemplary embodiments of the present disclosure will be described with reference to FIG. 2.

FIG. 2 is a block diagram showing an example of a control device configuration applicable to exemplary embodiments of the present disclosure. Each component shown in FIG. 2 may mainly show components related to exemplary embodiments of the present disclosure, and more or fewer components may be included in an actual implementation of the control device 140.

Referring to FIG. 2, the control device 140 may include a firmware management unit 141, a traffic control unit 142, a process management unit 143, a production/logistics management unit 144, an inventory management unit 145, a communication unit 146, a vehicle monitoring unit 147, and a map management unit 148.

The firmware management unit 141 may obtain the latest firmware of the smart logistics vehicle 110 through the communication unit 146 and transmit the same to the smart logistics vehicle 110 to perform a firmware update, thereby maintaining the latest firmware of the smart logistics vehicle 110.

The traffic control unit 142 may control traffic lights and barriers on the basis of the path of the smart logistics vehicle 110, and may recalculate the path of the smart logistics vehicle 110 according to traffic.

The process management unit 143 may define a process for each product and may manage missions such as the extent of a process progress and a progress location.

The production/logistics management unit 144 may dispatch the smart logistics vehicle 110 on a mission basis.

The inventory management unit 145 may manage the location and quantity of each material, and this information may be utilized to more efficiently operate the process, such as departing the smart logistics vehicle 110 to a destination for pallet pickup or collection in advance of the time when actual assembly/consumption of materials is detected.

The communication unit 146 may perform communication with not only internal components of the smart factory 100, such as the smart logistics vehicle 110, the production device 120, and the monitoring device 130, but also external entities, such as a firmware update server.

The vehicle monitoring unit 147 may monitor the location, path, battery status, communication status, and power train status of the individual smart logistics vehicle 110. Herein, the path may be a concept including a waypoint-based global path and a real-time local path. In addition, the battery status may include voltage, current, temperature, peak values of voltage and current, a state of charge (SOC), a state of health (SOH), and the like. The communication status may include information about a currently activated communication protocol (such as Wi-Fi), a connected AP, a distance to the AP, a channel in use, and the like. Additionally, the power train status may include a load, temperature, RPM, etc. of a driving system.

Besides, the vehicle monitoring unit 147 may identify the mission, operation mode, firmware version, and the like currently assigned to the individual smart logistics vehicle 110.

The map management unit 148 may obtain map data in the form of a grid map obtained when the AMR among the smart logistics vehicles 110 travels inside the smart factory 100, and may provide a tool for a factory manager to edit the obtained map data. When the smart logistics vehicle 110 enters, a zone where one or more preset actions are performed, a virtual lane, an intersection, no entry zone, etc. may be set through the editing of the map data, but this is only an example and is not necessarily limited thereto. In addition, the map management unit 148 may distribute through the communication unit 146 the corresponding map to the remaining smart logistics vehicles 110 other than the smart logistics vehicle 110 which obtains the initial grid map through the actual traveling.

Next, the smart logistics vehicle will be described with reference to FIGS. 3 and 4.

FIG. 3 is a block diagram showing an example of a smart logistics vehicle configuration applicable to exemplary embodiments of the present disclosure.

Referring to FIG. 3, the smart logistics vehicle 110 may include a traveling unit 111, a sensing unit 112, a loading unit 113, a communication unit 114, and a control unit 115. Hereinafter, each component will be described.

The traveling unit 111 may include a driving source, a wheel, a suspension, and the like, involved in the movement, steering, and stopping of the smart logistics vehicle 110. The driving source may be an electric motor supplied with power from a built-in battery (not shown). The wheel may include one or more driving wheels that are supplied with driving force from the driving source, and a non-driving wheel that is rotated by the movement of the vehicle body without receiving the driving force. Depending on an implementation, when a plurality of driving wheels are provided, the driving source may be matched to each driving wheel so that the rotation of each driving wheel can be independently controlled. In this case, by making the rotation directions of different driving wheels different, a steering can be achieved by rotating the vehicle body without a separate steering means. At least some of the non-driving wheels may be configured as caster type wheels, but this is exemplary and is not necessarily limited thereto.

The sensing unit 112 may be for sensing the surrounding environment of the smart logistics vehicle 110 or its own operating status, and may include at least one of a 2D laser scanner (e.g., LiDAR), a 3D vision (stereo) camera, a multi-axis gyro sensor, an acceleration sensor, a wheel encoder, and a proximity sensor.

The encoder may output information for determining how much the wheel has rotated by using light emitted from a light emitting device (e.g., a photodiode). For example, the encoder may count the number of slits disposed along the circumferential direction on the wheel or the disk rotating together with the wheel per unit time. The control unit 115 can perform an odometry which estimates a displacement by analyzing the amount of location change over time by using data obtained through the encoder and the gyro sensor. However, there could be errors between an actual displacement and the estimated displacement based on the encoder data because of wheel slip or wear (change in wheel dynamic radius). Therefore, when performing the odometry, the control unit 115 may perform a correction with respect to noise and error on the information collected from the wheel and gyro sensors by using a predetermined algorithm (e.g., EKF: Extended Kalman Filter) and output a result that has a tendency to be close to the actual value. Such an odometry may be particularly useful when current location determination (localization) using a 2D laser scanner is not possible, which will be described later.

The 2D laser scanner may radiate a laser beam onto the surrounding area through a rotating reflector and scan the surrounding environment by sensing the reflected and returned signal. In this case, a detection result of a point cloud shape may be output by analyzing the intensity of the reflected signal and the time difference between the irradiation and reception.

The 3D vision camera may calculate the distance to an object on the basis of the parallax between two cameras spaced apart by a predetermined distance, that is, the pixel distance between the images captured by each camera. In this case, a texture projector for projecting infrared light in a predetermined pattern may be provided in order to detect a flat body of the same color (e.g., a white wall).

In general, the 2D laser scanner may be used for mapping, navigation, object recognition, etc., and the 3D camera can be utilized especially for avoiding obstacles during navigation, but this is exemplary and is not necessarily limited.

The loading unit 113 may be a means for loading products, the targets to be transferred, and may be in the form of a top plate itself on the upper part of the vehicle body, a table disposed on the top plate, a lift, a turntable rotating along a vertical axis, a fork lift, a conveyor, or a combination thereof. In the case of the forklift, telescopic and tilting functions may be supported like a forklift truck.

The communication unit 114 may communicate with other components in the smart factory 100, such as the production device 120 and the control device 140, may support the communication between the smart logistics vehicles 110, and may communicate with a charger when performing a charging mission.

The control unit 115 may be an entity that performs overall control of each of the aforementioned components 111, 112, 113, 114, and may perform a current mission, a current location, a destination determination, a path planning, a load unit control, and the like on the basis of the information obtained from the control device 140 through the communication unit 114.

FIG. 4 is a perspective view showing an example of a smart logistics vehicle exterior applicable to exemplary embodiments of the present disclosure.

Referring to FIG. 4, an example of AMR may be illustrated as the smart logistics vehicle 110. The vehicle body may have a track-type planar shape having a long axis extending along a first-axis direction as a whole. One driving wheel 111-1 may be disposed in the center portion of the vehicle body in the first-axis direction and disposed at one side toward a second-axis direction, and another driving wheel (not shown) may be disposed at the other side toward the second-axis direction to face one driving wheel 111-1. Such an arrangement of driving wheels may be referred to as “a differential drive” (DD). Although not shown in FIG. 4, two or more non-driving wheels may be disposed at a lower portion of the vehicle body. In this case, it is possible to rotate forward or backward along the first axis direction when two driving wheels rotate at the same speed in the same direction, and possible to rotate on the basis of a rotation axis that extends along a third axis direction and passes through the plane center (C) of the vehicle body when rotating at the same speed in the opposite direction. In addition, the sensor unit 112 may be disposed at the front portion of the vehicle body, and the loading unit 113 may be disposed at the upper surface. The loading unit 113 may be configured to be able to rise and fall along the third axis direction, and a rack, a tray, or the like may be fixed to an upper surface thereof through a guide 113-1.

However, the AMR shape of FIG. 4 described above may be exemplary, and it may be obvious that the AGV has a shape similar to this or the AMR has a shape different from this.

Next, a traveling process of the smart logistics vehicle 110 will be described with reference to FIG. 5.

FIG. 5 is a flowchart showing an example of a traveling process of a smart logistics vehicle 110 applicable to exemplary embodiments of the present disclosure. In FIG. 5, it may be assumed for convenience that the smart logistics vehicle 110 is an AMR capable of positioning and a local path setting.

Referring to FIG. 5, first, the AMR may obtain a ground-truth grid map through LiDAR or the like while traveling inside the smart factory 100 (S501).

When the AMR transmits the obtained grid map to the control device 140, the map management unit 148 of the control device 140 may perform a grid map editing and matching process (S502). Herein, the editing process may include a process of setting the aforementioned various zones on the aforementioned grid map, a process of assigning a cost to each grid, and the like. Herein, the cost assignment may be performed in such a way that as the AMR is closer to an obstacle or no entry zone the cost is assigned higher in order to prevent the AMR from moving toward the obstacle or into no entry zone. This is because the AMR selects a set of cells with the lowest cost between waypoints as a path in setting the local path.

In addition, the map matching process may mean a process of matching coordinates between the CAD map used in the design of the smart factory 100, the ground truth grid map (LiDAR map), and the topology map that has gone through the editing process.

Thereafter, the control device 140 may share the topology map with all AMRs within the factory through the communication unit 146 (S503).

Subsequent steps may be a process applied to an individual AMR.

The AMR may determine the current location on the map (localization) through the sensor data of the sensing unit 112 and the obtained map (S504). For example, the AMR may compare the surrounding terrain obtained through the LiDAR with the map on the basis of feature points and determine the current location.

The control device 140 may assign a mission by selecting a specific AMR, and one or more waypoints determined through global path planning may be generally assigned to the mission. The waypoints may be defined as coordinates on the map, and may be accompanied by information about the direction (i.e., heading) in which the AMR should be directed at the corresponding coordinates. According to this mission assignment, a destination may be set in the AMR (Yes in S505), and the AMR may perform local path planning between waypoints on the basis of the cost of the topology map (S506).

When the path is determined, the AMR may start traveling (S507), and when an obstacle is detected through the sensing unit 112 during traveling (Yes in S508), may perform an avoidance maneuver by performing local path searching to bypass the detected obstacle (S509). In some cases, the control device 140 may update the mission of the corresponding AMR according to the avoidance maneuver, or according to the failure of the avoidance maneuver.

In addition, the AMR may correct the location error while moving through the aforementioned odometry technique until reaching the destination (S510).

Subsequently, when reaching the destination (S511), the AMR may perform a mission-based maneuver (S512). For example, the AMR may determine whether a condition for entering a specific process zone is clear, collect an empty pallet from the destination, or drop a loaded load on the loading unit 113.

In an exemplary embodiment of the present disclosure, an objective is to improve the process efficiency of the smart factory 100 and increase productivity by controlling a plurality of smart logistics vehicles located in the smart factory 100 into a plurality of groups.

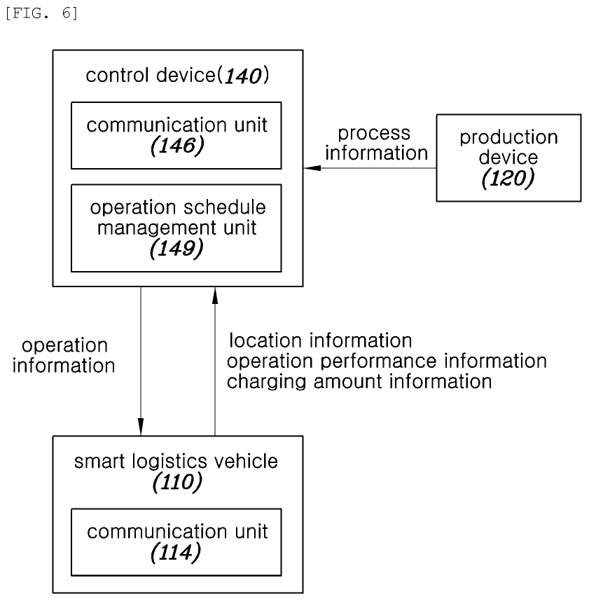

Hereinafter, a smart logistics vehicle control system according to an exemplary embodiment will be described with reference to FIG. 6.

FIG. 6 is a block diagram showing a configuration of a smart logistics vehicle control system according to an exemplary embodiment of the present disclosure.

Referring to FIG. 6, the smart logistics vehicle control system according to an exemplary embodiment of the present disclosure may include a plurality of smart logistics vehicles, a plurality of production devices, each provided in a plurality of process zones to control each process zone, collect and provide process information, and a control device 140 for controlling the plurality of smart logistics vehicles on the basis of the process information with respect to each of the plurality of process zones from the plurality of production devices.

In FIG. 6, it may be shown for convenience of explanation that one smart logistics vehicle 110 and one production device 120 exchange information with the control device 140, but it should be understood that the same applies to the plurality of smart logistics vehicles and the plurality of production devices.

The control device 140 may include a communication unit 146 and an operation schedule management unit 149, and may receive the process information or the information on the location, operation performance, and charging amount of the smart logistics vehicle 110.

In this case, the process information may be process-related information provided from the production device 120 provided in the process zone, or may be operation status information of the process zone provided from the monitoring device 130 when the monitoring device 130 is further provided in the process zone. However, this is exemplary, and is not necessarily limited thereto. Also, the information on the location, operation performance, and charging amount of the smart logistics vehicle 110 may be the information provided from the communication unit 114 of the smart logistics vehicle 110.

The control device 140 may generate operation information on the basis of input information and transmit the same to the smart logistics vehicle 110 to control the smart logistics vehicle 110 on the basis of the operation information.

Hereinafter, a specific function of the control device 140 will be described.

First, the communication unit 146 may communicate with at least one process controller connected to the production device 120. Herein, the process controller (not shown) may be implemented as, for example, a PLC described above.

The communication unit 146 may continuously receive the process information performed in the process zone from the production device 120, and may transmit the same to the operation schedule management unit 149 to allow the operation schedule management unit 149 to control the smart logistics vehicle 110.

In addition, the communication unit 146 can communicate with the communication unit 114 of the smart logistics vehicle 110, which enables identifying information about the location of the smart logistics vehicle 110, whether the operation of the smart logistics vehicle 110 is performed, and the current charging amount (SOC: state of charge), and transmitting the corresponding information to the operation schedule management unit 149 to control the smart logistics vehicle 110.

Meanwhile, the operation schedule management unit 149 may receive information through the communication unit 146 and generate the operation information of the smart logistics vehicle 110 on the basis of the received information. Specifically, the operation schedule management unit 149 may manage the plurality of smart logistics vehicles into a plurality of groups. Herein, the plurality of groups may be composed of a patrol group for performing a circling operation along the patrol path, an operation group for performing a logistics operation in each of the plurality of process zones, and a charging group for performing a charging operation when the charging amount of the smart logistics vehicle 110 is insufficient. In this case, the operation group for performing the logistics operation may be divided into a plurality of operation groups. For example, the operation group may be divided into an operation group for performing a logistics transfer operation where the logistics, where a process is completed in a process zone, is transferred to a next process zone, and an operation group for performing a logistics waiting operation for moving in advance to and waiting in a process zone in order to perform the logistics transfer operation. In addition, when configuring the plurality of groups, the number or paths of smart logistics vehicles included in each group may be set in various ways, and each group may be configured again into two or more small groups. However, this is merely exemplary, and is not necessarily limited thereto.

Further, a priority may be set in advance for each of the plurality of groups managed by the operation schedule management unit 149, and the priority for each of the plurality of groups may be set by an external signal (e.g., a manual operation of a manager managing the control device 140). The operation schedule management unit 149 may control the operation of the plurality of smart logistics vehicles to be performed according to the set priority. A plurality of operation commands may be input to the smart logistics vehicle 110, and the operation schedule management unit 149 may determine the priority of the operation group corresponding to the plurality of input operation commands and may control the corresponding smart logistics vehicle 110 to first perform the operation having the higher priority. For example, when an operation group performing a logistics transfer operation is given the 1st priority, a patrol group performing a circling operation is given the 2nd priority, and a charging group performing a charging operation is given the 3rd priority, and when the logistics transfer operation and the circling operation are input simultaneously into the smart logistics vehicle 110, the operation schedule management unit 149 may compare the priority of the logistics transfer operation and the priority of the circling operation and control the logistics transfer operation having the higher priority to be performed first. However, this is exemplary, and the priority for each of the plurality of groups may be formed in various ways depending on the process and operation conditions of the smart factory 100.

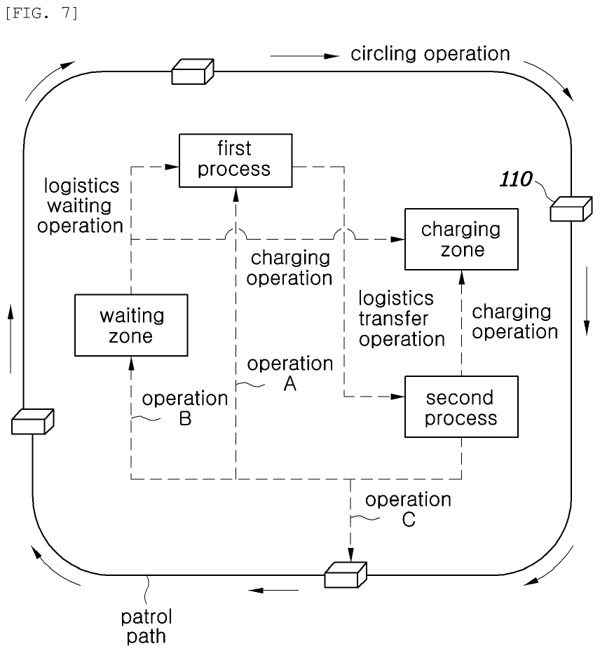

Hereinafter, the operation group will be briefly described with reference to FIG. 7.

FIG. 7 is a view illustrating a smart logistics vehicle control system according to an exemplary embodiment of the present disclosure.

Referring to FIG. 7, the smart logistics vehicle not performing an operation among the plurality of smart logistics vehicles may perform a circling operation along the patrol path. In FIG. 7, the patrol path may be formed by surrounding the plurality of process zones, but this is exemplary, and the patrol path may be formed in various ways, which will be described later about this. In addition, it is assumed for convenience of explanation that the plurality of process zones are composed of a process zone for performing a first process (hereinafter, referred to as a first process zone) and a process zone for performing a second process (hereinafter, referred to as a second process zone).

When the first process zone needs the smart logistics vehicle 110, at least one smart logistics vehicle among smart logistics vehicles performing a circling operation may move to the first process zone. The smart logistics vehicle 110 moved to the first process zone may perform a logistics transfer operation for transferring logistics to the second process zone. However, when the first process zone does not need the smart logistics vehicle 110 immediately, but needs the smart logistics vehicle 110 in order to secure the smart logistics vehicle 110 in advance, at least one smart logistics vehicle among the smart logistics vehicles performing a circling operation may move to a waiting zone formed near the first process zone and perform a logistics waiting operation. As shown in FIG. 7, the waiting zone may be formed separated from the first process zone, but this is exemplary and may be formed included in the first process zone.

Also, a smart logistics vehicle with an insufficient state of charge (SOC) among the smart logistics vehicles located in the waiting zone may move to the charging zone and perform a charging operation for charging. The charging operation may be performed for the smart logistics vehicle located in the waiting zone, but the charging operation may also be performed for the smart logistics vehicle completing the logistics transfer operation from the first process zone to the second process zone by checking the charging amount (SOC).

In addition, the smart logistics vehicle which finishes the logistics transfer operation toward the second process zone may perform one operation among a plurality of operations (operation A, operation B, and operation C) according to the process information of the first process zone. For example, when the smart logistics vehicle 110 is continuously needed in the first process zone, the operation (operation A) of moving to the first process zone may be performed in order to perform the logistics transfer operation or the operation (operation B) of moving to the waiting zone may be performed in order to perform the logistics waiting operation. When the smart logistics vehicle 110 is not needed in the first process zone, the operation (operation C) of moving to the patrol path may be performed in order to perform the circling operation. However, specific details thereof will be described later.

Referring back to FIG. 6, the operation schedule management unit 149 may provide the operation information to the communication unit 114 of the corresponding smart logistics vehicle 110 so that the smart logistics vehicle 110 not performing an operation among the plurality of smart logistics vehicles can perform the circling operation along a preset patrol path on the basis of the location information provided from each of the plurality of smart logistics vehicles and the information on whether the operation are performed.

Herein, the patrol path may be generated in the map management unit 148 of the control device 140 described above, and a factory manager may generate the patrol path by designating a start point and an end point and by designating a plurality of nodes or ports on the basis of the map data of the smart factory 100. In this case, the operation schedule management unit 149 may determine the generated patrol path as a preset patrol path and allow the plurality of smart logistics vehicles to perform the circling operation. In addition, the operation schedule management unit 149 may allow the plurality of smart logistics vehicles to perform the circling operation at a low speed along the generated patrol path.

Also, the operation schedule management unit 149 may determine whether at least one process zone among the plurality of process zones needs the smart logistics vehicle 110 on the basis of the process information provided from the production device 120. When at least one process zone among the plurality of process zones needs the smart logistics vehicle 110, the operation schedule management unit 149 may select at least one smart logistics vehicle among the plurality of smart logistics vehicles and send the same to at least one process zone needing the smart logistics vehicle 110.

To this end, the operation schedule management unit 149 may obtain information about the smart logistics vehicle performing the circling operation and the smart logistics vehicle performing the logistics operation in at least one process zone. The operation schedule management unit 149 may select at least one smart logistics vehicle among smart logistics vehicles performing the circling operation, or may select at least one smart logistics vehicle among smart logistics vehicles performing the logistics operation in at least one process zone, on the basis of the obtained information. In this case, the logistics operation in the at least one process zone may refer to the logistics waiting operation, and thus, the smart logistics vehicle performing the logistics operation in the at least one process zone may refer to the smart logistics vehicle performing the logistics waiting operation after finishing the logistics transfer operation. However, this is exemplary and is not necessarily limited thereto.

Specifically, the operation schedule management unit 149 may collect location information on each smart logistics vehicle included in the patrol group for performing the circling operation, and location information on each smart logistics vehicle performing the logistics operation in at least one process zone. Also, when a process zone needs the smart logistics vehicle 110, the operation schedule management unit 149 may determine the movement path between each smart logistics vehicle performing the circling operation or each smart logistics vehicle performing the logistics operation and the corresponding process zone, on the basis of each location information. The operation schedule management unit 149 may select the smart logistics vehicle having the shortest movement path among the determined movement paths. In the present disclosure, it is assumed that there is the smart logistics vehicle having the shortest movement path among the smart logistics vehicles performing the circling operation, as an example.

Meanwhile, in determining the movement path, there may be a plurality of smart logistics vehicles 110 having the shortest movement path among the determined movement paths. In this case, the operation schedule management unit 149 may select one smart logistics vehicle among a plurality of smart logistics vehicles having the shortest movement path, on the basis of an additional status condition. For example, the additional status condition may include whether to be an appropriate battery SOC of the smart logistics vehicle, an operation priority, whether to be forcibly selected, a traveling status, and the like. However, this is exemplary, and it is obvious that fewer or more conditions than the conditions described above may be considered.

The operation schedule management unit 149 may control the selected smart logistics vehicle 110 to finish performing the circling operation and to deviate from the patrol group. The operation schedule management unit 149 may manage at least one smart logistics vehicle deviated from the patrol group as the operation group for moving to the process zone needing the smart logistics vehicle 110 and performing the logistics operation.

That is, since there are a plurality of logistics operations as described above, the operation schedule management unit 149 may allow at least one smart logistics vehicle among smart logistics vehicles performing the circling operation to move to the process zone needing the smart logistics vehicle 110 and to perform the logistics transfer operation. In addition, the operation schedule management unit 149 may allow at least one smart logistics vehicle among smart logistics vehicles performing the circling operation to move to a waiting zone formed near the process zone needing the smart logistics vehicle 110 for waiting in advance before performing the logistics transfer operation and to perform the logistics waiting operation.

In addition, the operation schedule management unit 149 may collect the operation performance information from the smart logistics vehicles performing the logistics operation and determine whether the logistics operation is completed. When there is the smart logistics vehicle completing to perform the logistics operation, it is possible to control the smart logistics vehicle completing to perform the logistics operation by determining whether there is another process zone needing the smart logistics vehicle 110 or the charging amount (SOC) of the smart logistics vehicle completing to perform the logistics operation on the basis of the process information provided by the production device 120.

When there is another process zone needing the smart logistics vehicle 110, the operation schedule management unit 149 may allow the smart logistics vehicle completing to perform the logistics operation to move to the corresponding process zone and to perform a new logistics operation. Even at this time, the operation schedule management unit 149 may allow the smart logistics vehicle completing to perform the logistics operation to perform the logistics transfer operation or to perform the logistics waiting operation, as described above.

However, when there is no process zone needing the smart logistics vehicle 110, the operation schedule management unit 149 may allow the smart logistics vehicle completing to perform the logistics operation to perform the circling operation of circling along the preset patrol path. That is, the operation schedule management unit 149 may allow the smart logistics vehicle completing to perform the logistics operation to deviate from the operation group and allow the deviated smart logistics vehicle to rejoin the patrol group.

In addition, when there is no process zone needing the smart logistics vehicle 110, the operation schedule management unit 149 may check the charging amount (SOC) of the smart logistics vehicle completing to perform the logistics operation. When the charging amount (SOC) is insufficient, the smart logistics vehicle completing to perform the logistics operation may move to the charging zone and perform the charging operation. That is, the operation schedule management unit 149 may allow the smart logistics vehicle completing to perform the logistics operation to deviate from the operation group and allow the deviated smart logistics vehicle to rejoin the charging group.

However, the charging operation may be an operation having a lower priority than the logistics operation and the circling operation, and the operation schedule management unit 149 may not perform the control of the smart logistics vehicle 110 in consideration of the charging amount (SOC) of the smart logistics vehicle 110. For example, the operation schedule management unit 149 may allow each of the plurality of smart logistics vehicles to perform the logistics operation or the circling operation without considering the charging amount (SOC) of the smart logistics vehicle 110.

As described above, the operation schedule management unit 149 of the present disclosure may control the plurality of smart logistics vehicles by generating various operation information with respect to each of the plurality of smart logistics vehicles. This can improve the process efficiency of the smart factory 100 and increase productivity.

Meanwhile, the operation schedule management unit 149 in the present disclosure may generate the operation information for controlling the plurality of smart logistics vehicles, but this is exemplary, and it is obvious that the operation schedule management unit 149 may be divided into and configured with a plurality of configurations each performing the roles described above.

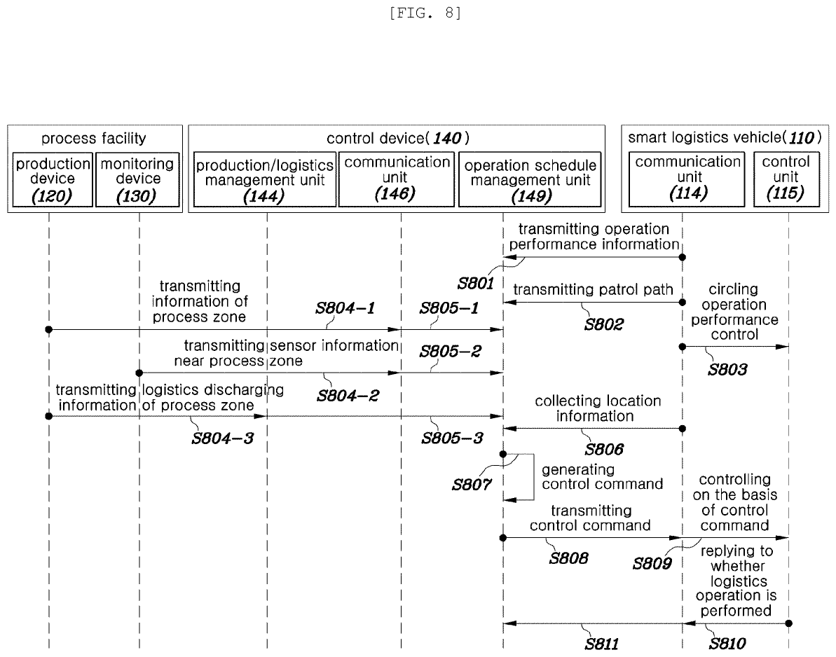

Hereinafter, with reference to FIG. 8, a smart logistics vehicle control method according to an exemplary embodiment will be described on the basis of the configuration of the smart logistics vehicle control system of FIGS. 6 to 7 described above.

FIG. 8 is a view illustrating a smart logistics vehicle control method according to an exemplary embodiment of the present disclosure.

Referring to FIG. 8, the communication unit 114 of the smart logistics vehicle 110 may transmit the operation performance information to the control device 140 (S801). The operation schedule management unit 149 of the control device 140 may generate and transmit a patrol path to a smart logistics vehicle not performing an operation on the basis of the operation performance information (S802).

The communication unit 114 of the smart logistics vehicle not performing an operation may receive the patrol path and transmit a circling operation performance control command to the control unit 115 so that a circling operation can be performed on the basis of the received patrol path (S803).

The communication unit 146 may receive process information of a process zone from the production device 120 (S804-1). Also, according to an exemplary embodiment, the communication unit 146 may receive sensor information collected through a sensor near the process zone through the monitoring device 130 installed around the process zone (S804-2). In addition, according to an exemplary embodiment, the production/logistics management unit 144 rather than the communication unit 146 may receive information related to logistics discharging of the process zone provided from the production device 120 (S804-3).

Thereafter, the communication unit 146 may transmit the process information of the process zone to the operation schedule management unit 149 (S805-1, S805-2), and the production/logistics management unit 144 may transmit the logistics discharging information of the process zone to the operation schedule management unit 149 (S805-3).

The operation schedule management unit 149 may determine the process zone needing the smart logistics vehicle 110 among the plurality of process zones on the basis of the received information, and may generate a control command for moving to the corresponding process zone and performing an operation. To this end, the operation schedule management unit 149 may collect the location information from the communication unit 114 of each of the plurality of smart logistics vehicles (S806), and on the basis of the collected location information and the information provided from the production/logistics management unit 144 or the communication unit 146 of the control device 140, may select at least one smart logistics vehicle and generate a control command so that the at least one selected smart logistics vehicle can move to at least one process zone needing the smart logistics vehicle (S807). A detailed description of this will be omitted as it is described above with reference to FIGS. 6 and 7.

Also, the operation schedule management unit 149 may transmit the generated control command to the communication unit 114 of the selected smart logistics vehicle (S808), and the communication unit 114 of the smart logistics vehicle may transmit the control command to the control unit 115 so that the control unit 115 can control the smart logistics vehicle on the basis of the control command (S809). For example, the control command generated by the operation schedule management unit 149 may include a circling operation stop command and a logistics operation performance command. Accordingly, the operation schedule management unit 149 may transmit the circling operation stop command to the communication unit 114 of at least one smart logistics vehicle among the smart logistics vehicles performing the circling operation and transmit the generated logistics operation command.

The communication unit 114 that receives the circling operation stop command and the logistics operation information may transmit the circling operation stop command to the control unit 115 and control the corresponding smart logistics vehicle to stop performing the circling operation. In addition, the communication unit 114 may transmit the logistics operation information to the control unit 115 and control the corresponding smart logistics vehicle to perform the logistics operation.

In the process of performing the logistics operation, the control unit 115 may reply to the communication unit 114 whether the logistics operation is performed (S810), and the communication unit 114 may transmit to the operation schedule management unit 149 the received information on whether the logistics operation is performed (S811). On the basis of the information received from the communication unit 114, the operation schedule management unit 149 may again transmit to the communication unit the information for controlling the smart logistics vehicle completing to perform the logistics operation. Since this is the same as the process performed in steps S802 to S808, a description thereof will be omitted.

Although shown and described with reference to specific exemplary embodiments of the present disclosure, it will be apparent to those skilled in the art that the present disclosure may be variously improved and changed without departing from the technical idea of the present disclosure as defined by the following claims.

The present disclosure described above can be implemented as computer-readable codes on a medium where a program is recorded. The computer-readable medium may include all types of recording devices that store data readable by a computer system. Examples of computer-readable media may include hard disk drives (HDDs), solid state disks (SSDs), silicon disk drives (SDDs), ROMs, RAMs, CD-ROMs, magnetic tapes, floppy disks, optical data storage devices, and the like. Therefore, the detailed description above should not be construed as limiting in all respects but should be considered illustrative. The scope of the present disclosure should be determined by reasonable interpretation of the appended claims, and all changes within the equivalent scope of the present disclosure are included in the scope of the present disclosure.

### DESCRIPTION OF REFERENCE NUMERALS

100: smart factory
110: smart logistics vehicle
120: production device
130: monitoring device
140: control device

1. A smart logistics vehicle control method, the method comprising:
controlling a smart logistics vehicle not performing an operation among a plurality of smart logistics vehicles to perform a circling operation along a preset patrol path;
determining whether the smart logistics vehicle is necessary for each of a plurality of process zones;
selecting at least one smart logistics vehicle among the smart logistics vehicles performing the circling operation when the smart logistics vehicle is necessary for at least one process zone among the plurality of process zones; and
controlling the at least one selected smart logistics vehicle to stop performing the circling operation and to move to the at least one process zone and perform a logistics operation.

2. The method of claim 1, wherein the determining comprises:
collecting process information of each of the plurality of process zones from a plurality of production devices that control each of the plurality of process zones; and
determining whether the smart logistics vehicle is necessary for each of the plurality of process zones based on the process information collected from each of the plurality of process zones.

3. The method of claim 1, wherein when the smart logistics vehicle is necessary for at least one process zone among the plurality of process zones, the selecting comprises:
obtaining information about the smart logistics vehicle performing the circling operation and the smart logistics vehicle performing the operation in the at least one process zone; and
selecting the at least one smart logistics vehicle based on the obtained information.

4. The method of claim 1, wherein the controlling the at least one selected smart logistics vehicle comprises:
collecting location information with respect to each smart logistics vehicle performing the circling operation;
determining a movement path between the smart logistics vehicle performing the circling operation and the at least one process zone when the smart logistics vehicle is necessary for at least one process zone among the plurality of process zones based on the location information; and
controlling the smart logistics vehicle having a shortest movement path among the movement paths to finish performing the circling operation and to move to the at least one process zone and perform the logistics operation.

5. The method of claim 4, wherein the controlling the at least one selected smart logistics vehicle comprises:
controlling the smart logistics vehicle selected based on an additional status condition to finish performing the circling operation and to move to the at least one process zone and perform the logistics operation when there are a plurality of smart logistics vehicles having the shortest movement path among the movement paths.

6. The method of claim 4, wherein the controlling the at least one selected smart logistics vehicle comprises:
controlling the smart logistics vehicle having the shortest movement path among the movement paths to finish performing the circling operation and to move to the at least one process zone and perform a logistics transfer operation.

7. The method of claim 6, wherein the controlling the at least one selected smart logistics vehicle further comprises:
controlling the smart logistics vehicle having the shortest movement path among the movement paths to finish performing the circling operation and to move to a waiting zone for waiting in advance and perform a logistics waiting operation before moving to the at least one process zone to perform the logistics transfer operation.

8. The method of claim 1, wherein
after the controlling the at least one selected smart logistics vehicle, the method further comprises:
determining whether the logistics operation of the smart logistics vehicle moved to the at least one process zone is completed; and
controlling the smart logistics vehicle completing the logistics operation by determining whether there is another process zone needing the smart logistics vehicle or a charging amount (SOC: state of charge) of the smart logistics vehicle completing the logistics operation when the logistics operation of the smart logistics vehicle is completed.

9. The method of claim 8, wherein the controlling the smart logistics vehicle comprises:
controlling the smart logistics vehicle completing the logistics operation to move to the process zone and perform a new logistics operation when there is another process zone needing the smart logistics vehicle.

10. The method of claim 8, wherein the controlling the smart logistics vehicle further comprises:
controlling the smart logistics vehicle completing the logistics operation to perform the circling operation along the preset patrol path when there is no other process zone needing the smart logistics vehicle.

11. The method of claim 8, wherein the controlling the smart logistics vehicle further comprises:
controlling the smart logistics vehicle completing the logistics operation to move to a charging zone and perform a charging operation when there is no other process zone needing the smart logistics vehicle and the charging amount (SOC: state of charge) of the smart logistics vehicle completing the logistics operation is less than a predetermined value.

12. A smart logistics vehicle control system, the system comprising:
a plurality of smart logistics vehicles;
a plurality of production devices, each provided in a plurality of process zones, for controlling each process zone and collecting and providing process information; and
an operation schedule management unit for controlling the smart logistics vehicle not performing an operation among the plurality of smart logistics vehicles to perform a circling operation along a preset patrol path, selecting at least one smart logistics vehicle among the smart logistics vehicles performing the circling operation when the smart logistics vehicle is necessary for at least one process zone among the plurality of process zones by determining whether the smart logistics vehicle is required based on the process information, and controlling the at least one selected smart logistics vehicle to finish performing the circling operation and to move to the at least one process zone and perform a logistics operation.

13. The system of claim 12, wherein the operation schedule management unit manages the plurality of smart logistics vehicles into a plurality of groups, and the plurality of groups are composed of a patrol group for performing the circling operation along the patrol path, an operation group for performing the logistics operation in each of the plurality of process zones, and a charging group for performing a charging operation when a charging amount of the plurality of smart logistics vehicles is less than a predetermined value.

14. The system of claim 13, wherein the operation schedule management unit manages the smart logistics vehicle not performing the operation as the patrol group, and manages at least one smart logistics vehicle among the smart logistics vehicles included in the patrol group as the operation group when the smart logistics vehicle is necessary for the at least one process zone.

15. The system of claim 12, wherein the operation schedule management unit obtains information about the smart logistics vehicle performing the circling operation and the smart logistics vehicle performing the operation in the at least one process zone, and selects the at least one smart logistics vehicle based on the obtained information when the smart logistics vehicle is necessary for at least one process zone among the plurality of process zones.

16. The system of claim 12, wherein the operation schedule management unit collects location information with respect to each smart logistics vehicle performing the circling operation, determines a movement path between the smart logistics vehicle performing the circling operation and the at least one process zone based on the location information when the smart logistics vehicle is necessary for at least one process zone among the plurality of process zones, and controls the smart logistics vehicle having a shortest movement path among the movement paths to finish performing the circling operation and to move to the at least one process zone and perform the logistics operation.

17. The system of claim 16, wherein the operation schedule management unit controls the smart logistics vehicle having the shortest movement path among the movement paths to finish performing the circling operation and to move to the at least one process zone and perform a logistics transfer operation.

18. The system of claim 12, wherein the operation schedule management unit determines whether the logistics operation of the smart logistics vehicle moved to the at least one process zone is completed, determines whether there is another process zone needing the smart logistics vehicle when the logistics operation of the smart logistics vehicle is completed or a charging amount (SOC: state of charge) of the smart logistics vehicle completing the logistics operation and controls the smart logistics vehicle completing the logistics operation.

19. The system of claim 18, wherein the operation schedule management unit controls the smart logistics vehicle completing the logistics operation to move to the process zone and perform a new logistics operation when there is another process zone needing the smart logistics vehicle.

20. The system of claim 18, wherein the operation schedule management unit controls the smart logistics vehicle completing the logistics operation to move to a charging zone and perform a charging operation when there is no other process zone needing the smart logistics vehicle and a charging amount (SOC: state of charge) of the smart logistics vehicle completing the logistics operation is less than a predetermined value.
